(19) United States
(12) Patent Application Publication
(10) Pub. No.: US 2025/0062129 A1
(43) Pub. Date: Feb. 20, 2025

(54) DIE BACKSIDE PROFILE for SEMICONDUCTOR DEVICES

(71) Applicant: Applied Materials, Inc., Santa Clara, CA (US)

(72) Inventors: Yin Wei LIM, Singapore (SG); Guan Huei SEE, Singapore (SG); Chang Bum YONG, Singapore (SG); Prayudi LIANTO, Singapore (SG); Arvind SUNDARRAJAN, Singapore (SG); Cheng SUN, Singapore (SG)

(21) Appl. No.: 18/450,466

(22) Filed: Aug. 16, 2023

(51) Int. Cl. H01L 21/3065; H01L 23/00; H01L 25/065

(52) U.S. Cl. CPC H01L 21/3065; H01L 24/05; H01L 24/08; H01L 25/0657; H01L 24/95; H01L 2224/05624; H01L 2224/05639; H01L 2224/05644; H01L 2224/05647; H01L 2224/05666; H01L 2224/05671; H01L 2224/05686; H01L 2224/08145; H01L 2224/95; H01L 2924/0549; H01L 2924/10156; H01L 2924/10158

(57) ABSTRACT

Embodiments of the disclosure include an apparatus and method of forming a backside profile in a semiconductor device that includes die-to-wafer bonding. The method generally includes removing a portion of a substrate layer included in a plurality of dies, the plurality of dies arranged on and bonded to an insulation layer included in a support structure, where the plurality of dies define a plurality of channels between adjacent dies, and forming a corner feature on a plurality of corners of the substrate layer adjacent to the plurality of channels. The use of a backside profile as described herein may mitigate the downstream process risks associated with trapped residue in the channels, and provide stress relief to the semiconductor device.

### BACKGROUND

### Field

Embodiments described herein generally relate to semiconductor device fabrication. More specifically, embodiments of the present disclosure relate to semiconductor devices with die-to-wafer bonding that include a backside profile and methods of forming the same.

### Description of the Related Art

Performing die (e.g., semiconductor chip) to wafer (e.g., substrate) bonding results in gaps between adjacent dies on the wafer. These gaps may be referred to as inter-die spacing. As semiconductor device technology progresses, the length of inter-die spacing continues to decrease. Current die-to-wafer bonding often results in inter-die spacing of 100 micrometers (μm) or less. However, as the inter-die spacing decreases, the risk of trapped residue in the inter-die spacing increases. Trapped residue often creates several problems during semiconductor device fabrication, including challenges and risks in downstream processes.

Therefore, there is a need in the art for methods and apparatus to address the problems described above.

### SUMMARY

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

Embodiments of the present disclosure provide a method. The method generally includes removing a portion of a substrate layer included in a plurality of dies. The plurality of dies are arranged on and bonded to an insulation layer included in a support structure. The plurality of dies define a plurality of channels between adjacent dies. The method also generally includes forming a corner feature on a plurality of corners of the substrate layer adjacent to the plurality of channels.

Embodiments of the present disclosure provide an interconnect structure. The interconnect structure generally includes a support structure including an insulation layer and a plurality of dies arranged on and bonded to the insulation layer. The plurality of dies include a substrate layer, and the plurality of dies define a plurality of channels between adjacent dies. The interconnect structure generally also includes a corner feature included on a plurality of corners of the substrate layer adjacent to the plurality of channels.

Embodiments of the present disclosure provide an interconnect structure. The interconnect structure generally includes a support structure including an insulation layer, and a plurality of dies arranged on and bonded to the insulation layer. The plurality of dies include a substrate layer. The plurality of dies also define a plurality of channels between adjacent dies, and at least one sidewall of the plurality of dies is tapered.

Embodiments of the present disclosure provide a semiconductor device with die-to-wafer bonding that includes a backside profile as described herein.

### BRIEF DESCRIPTION OF THE DRAWINGS

So that the manner in which the above recited features of embodiments of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a top view of a portion of a semiconductor device with die-to-wafer bonding, in which embodiments of the present disclosure may be implemented.

FIG. 1B illustrates a cross-sectional view taken along the section line 1B in FIG. 1A, in which embodiments of the present disclosure may be implemented.

FIG. 2 is a flow diagram depicting a method of forming a backside profile on a semiconductor device that includes die-to-wafer bonding, according to one or more of the embodiments described herein.

FIGS. 3A, 3B, 3C, and 3D illustrate schematic side cross-sectional views of a portion of a semiconductor device during formation, according to one or more of the embodiments described herein.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure generally relate to a semiconductor device with die-to-wafer bonding that includes a backside profile and methods of forming the same. The semiconductor device may include a plurality of dies bonded to a support structure that includes a wafer. The backside profile described herein may be formed on a backside of one or more bonded dies included in the semiconductor device. The backside profile may include one or both of a plurality of corner features formed in the dies and a plurality of tapered sidewalls formed on the dies.

The use of the backside profile formed in accordance with embodiments and techniques of the present disclosure may relieve stress along edges of the dies and may reduce cracks in insulation layers included in the dies and the support structure during planarization.

### Die-to-Wafer Bonding for Semiconductor Devices Example

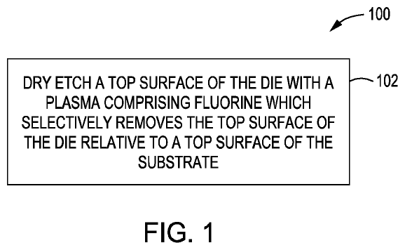

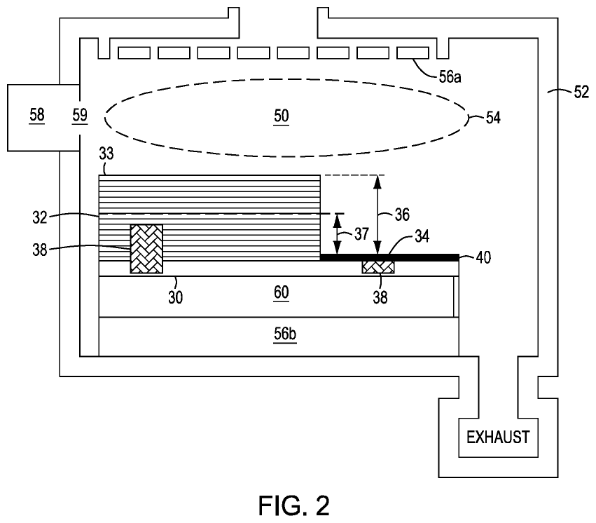

FIG. 1A illustrates a top view of portion of a semiconductor device 100 with die-to-wafer bonding, in which embodiments of the present disclosure may be implemented. FIG. 1B illustrates a cross-sectional view taken along the section line 1B in FIG. 1A, in which embodiments of the present disclosure may be implemented. Therefore, FIGS. 1A and 1B are herein described together for clarity. FIGS. 1A and 1B include an X-Y-Z coordinate system to show the orientation of the die-to-wafer bonding of the semiconductor device 100.

The die-to-wafer bonding of the semiconductor device 100 includes a plurality of dies 102 (e.g., semiconductor chips or blocks of semiconducting material on which a given functional circuit is fabricated). Each of the dies 102 may have a height H between 30 micrometers (μm) and 150 μm. Each of the dies 102 is arranged in a pattern on a support structure 106. As illustrated in FIGS. 1A and 1B, the pattern of the dies 102 results in channels 104 (e.g., gaps) between adjacent dies 102. These channels 104 may be referred to as the inter-die spacing. In some embodiments, a length L1 of the channels 104 may be between 50 μm and 4 millimeters (mm). The length L1 of the channel may be measured from a corner of one of the dies 102 to a corner of another adjacent die 102, as illustrated. In some cases, the length L1 of the channels 104 may be 100 μm or less. The channels 104 may each have the same length, or different lengths.

As the inter-die spacing (e.g., the length L1 of the channels 104) decreases, the risk of trapped residue in the inter-die spacing increases. FIG. 1B illustrates a portion of trapped residue 108 disposed in the channel 104. The trapped residue 108 may cause several problems during semiconductor device fabrication, including challenges and risks in downstream processes. In some cases, during processing of a semiconductor device 100 with die-to-wafer bonding, an oxide may be deposited in the inter-die spacing, and the trapped residue 108 may inhibit and negatively impact the deposition of the oxide. In some cases, oxide peeling may occur when trapped residue is not removed.

Embodiments of the present disclosure may involve forming a backside profile on a backside of a plurality of bonded dies included in a semiconductor device, e.g., the semiconductor device 100. The backside profile may include or be implemented as at least one of a plurality of corner features formed in the dies 102 or a plurality of tapered sidewalls formed on the dies 102, as will be described herein. The use of the backside profile may reduce the occurrence of problematic trapped residue 108 in the channels 104 between adjacent dies 102. As a result, the downstream process risks are mitigated, and stress relief is provided to the semiconductor device 100, especially at the interface between the die 102 backside and insulation layers. For example, reducing the occurrence of the trapped residue 108 may relieve stress along edges (e.g., sidewalls) of the dies 102 and may reduce cracks in insulation (e.g., dielectric) layers included in the dies and the support structure 106 during planarization.

### Die Backside Profile Formation and Structure

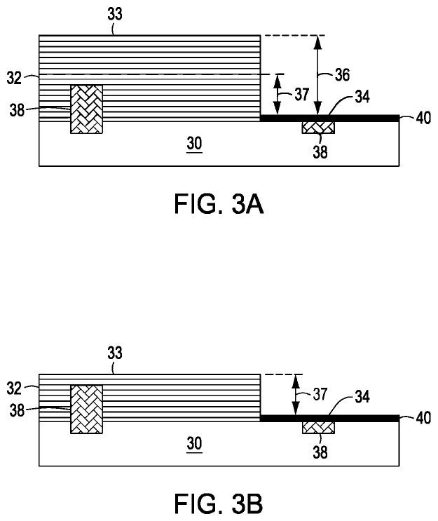

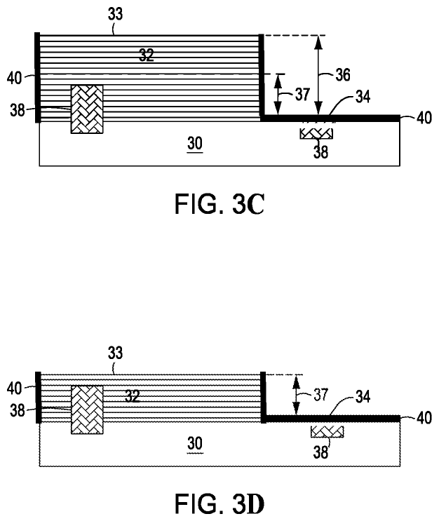

FIG. 2 is a flow diagram depicting a method 200 of forming a backside profile on a semiconductor device that includes die-to-wafer bonding, according to one or more of the embodiments described herein. FIGS. 3A, 3B, 3C, and 3D illustrate schematic side cross-sectional views of a portion 300 of a semiconductor device during one or more of the activities illustrated in FIG. 2, according to one or more of the embodiments described herein. Therefore, FIG. 2 and FIGS. 3A, 3B, 3C, and 3D are herein described together for clarity. The portion 300 of the semiconductor device may be considered or implemented as an interconnect structure included in the semiconductor device. It is assumed that the portion 300 of the semiconductor device includes a plurality of dies (e.g., dies 102) and a support structure (e.g., support structure 106) previously fabricated. The backside profile may be formed on the dies 102 of the semiconductor device. In addition, FIG. 3A illustrates the dies 102 and the support structure 106 before the dies 102 are bonded to the support structure 106. Although FIGS. 3A-3D depict only two dies 102, any number of dies 102 may be present. FIGS. 3A-3D include an X-Y-Z coordinate system to show the orientation of the portion 300 of the semiconductor device.

As illustrated in FIG. 3A, the dies 102 may include a substrate layer 302, one or more insulation layers 304a, 304b, and one or more local interconnects 306a, 306b. The one or more insulation layers 304a, 304b may be coupled to and disposed below the substrate layer 302. The one or more local interconnects 306a, 306b may be disposed in the insulation layers 304a, 304b. Although FIGS. 3A-3D illustrate two insulation layers 304a, 304b, any number of insulation layers may be used.

The term “substrate layer” as used herein may refer to a layer of material that serves as a basis for subsequent processing operations and includes a surface to be cleaned. The substrate layer 302 may be a silicon based material or any suitable insulating materials or conductive materials as needed. The substrate layer 302 may include a material such as crystalline silicon (e.g., Si<100>or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire. The substrate layer 302 may also be implemented as a wafer.

In some embodiments, the substrate layer 302 may be or be implemented as, for example, a doped or undoped silicon substrate, a III-V compound substrate, a silicon germanium (SiGe) substrate, an epi-substrate, a silicon-on-insulator (SOI) substrate, a display substrate such as a liquid crystal display (LCD), a plasma display, an electro luminescence (EL) lamp display, a light emitting diode (LED) substrate, a solar cell array, solar panel, or the like.

The substrate layer 302 is not limited to any particular size or shape. The substrate layer 302 can be a round wafer having a 200 mm diameter, a 300 mm diameter or other diameters, such as 450 mm, among others. The substrate layer 302 can also be any polygonal, square, rectangular, curved or otherwise non-circular workpiece, such as a polygonal glass substrate used in the fabrication of flat panel displays.

The one or more insulation layers 304a, 304b may include or be implemented as one or more dielectric layers. The dielectric layers may include at least one of silicon nitride (Si₃N₄), silicon carbon nitride (SiCN), silicon dioxide (SiO₂), silicon carbide (SiC), aluminum oxide (Al₂O₃), aluminum nitride (AlN), or the like. The one or more local interconnects 306a, 306b may include or be implemented as at least one of a damascene structure, a via, a trench, a pad, or the like. The local interconnects 306a, 306b may include, chromium, titanium, gold, silver, copper, aluminum, indium tin oxide (ITO), a combination thereof, or other suitably conductive materials. Although the portion 300 of the semiconductor device illustrated in FIG. 3A has two local interconnects 306a, 306b, any number of local interconnects may be included.

As illustrated in FIG. 3A, the support structure 106 may include a substrate layer 312, one or more insulation layers 314a, 314b, and one or more local interconnects 316a, 316b, 316c, 316d, 316e, 316f. The one or more insulation layers 314a, 314b may be coupled to and disposed above the substrate layer 312, as illustrated in FIG. 3A. The one or more local interconnects 316a, 316b, 316c, 316d, 316e, 316f may be disposed in the insulation layers 314a, 314b. Although the portion 300 illustrated in FIG. 3A has six local interconnects 316a, 316b, 316c, 316d, 316e, 316f, any number of local interconnects may be used. In addition, even though the portion 300 of the semiconductor device illustrated in FIG. 3A has two insulation layers 314a, 314b, any number of insulation layers may be included. As illustrated, some of the local interconnects (e.g., local interconnects 316c, 316d) may be implemented differently than other local interconnects (e.g., local interconnects 316a, 316b, 316e, 316f), and may not run the full height of the insulation layers 314a, 314b, as illustrated.

The substrate layer 312 of the support structure 106 may be implemented in the same manner or similarly to the substrate layer 302 of the dies 102 which is described above. The one or more insulation layers 314a, 314b of the support structure 106 may be implemented in the same manner or similarly to the one or more insulation layers 304a, 304b of the dies 102 which are described above. The one or more local interconnects 316a, 316b of the support structure 106 may be implemented in the same manner or similarly to the one or more local interconnects 306a, 306b of the dies 102 which are described above.

Die-to-wafer bonding may be performed on the dies 102 such that the dies are bonded to the support structure 106, as illustrated in FIG. 3B. In some embodiments, the bottom insulation layer 304a of the dies 102 may be bonded to the top insulation layer 314a of the support structure 106, as illustrated in FIG. 3B. In addition, the one or more local interconnects 306a, 306b of the dies 102 may be bonded to adjacent local interconnects 316a, 316b, 316e, 316f of the support structure 106, also as illustrated in FIG. 3B.

A plurality of connections (e.g., connections configured to route electricity) may be formed between adjacent interconnects of the local interconnects 306a, 306b and the local interconnects 316a, 316b, 316e, 316f. The plurality of connections between local interconnects 306a, 306b of the dies 102 and the local interconnects 316a, 316b, 316c, 316d, 316e, 316f of the support structure 106 may form a plurality of global interconnects 326a, 326b, 326c, 326d, as illustrated in FIG. 3B. The local interconnects 316c, 316d may not be configured to form global interconnects when the dies 102 are bonded to the support structure 106, also as illustrated in FIG. 3B.

As described above, each of the bonded dies 102 may be arranged in a pattern on the support structure 106. As illustrated in FIG. 3B (and in FIGS. 1A and 1B described above), the pattern of the dies 102 results in channels 104 (e.g., gaps) between adjacent dies 102. Also as described above, the length L1 of the channels 104 may be between 50 μm and 4 mm. The length L1 of the channel may be measured from a corner of one die 102 to a corner of another adjacent die 102, as illustrated. In some cases, the length L1 of the channels 104 may be 100 μm or less. The channels 104 may each have the same length, or different lengths. Although FIGS. 3A-3D depict only two dies 102 and a single channel 104, any number of dies 102 and associated channels 104 may be present.

The method 200 includes, at activity 202, removing a portion of the substrate layer 302 included in the plurality of dies 102, as illustrated in FIG. 3B. The portion of the substrate layer 302 that is removed may be a top portion of the substrate layer 302, and the removal results from an etch process (e.g., the first reactive ion etch (RIE) process described below) performed by an etching tool (not shown) disposed above the substrate layer 302 (e.g., in the Z-direction). As described above, the plurality of dies 102 may be arranged on and bonded to the top insulation layer 314a of the support structure 106. Also as described above, the plurality of dies 102 may define the plurality of channels 104 between adjacent dies 102.

In some embodiments, removing the portion of the substrate layer 302 included in the plurality of dies 102 (e.g., activity 202) includes etching the portion of the substrate layer 302 by the first RIE process. A ratio of a selectivity of the first RIE process between the substrate layer 302 and the insulation layer 314a is at least 100:1. In some cases, the ratio selectivity of the first RIE process between the substrate layer 302 and the insulation layer 314a may be configured such that the first RIE process is a predominately vertical etch of the substrate layer 302, etching a smaller portion of the insulation layer 314a.

The first RIE process may include using at least one of sulfur hexafluoride (SF₆), methyl fluoride (CH₃F), or octafluorocyclobutane (C₄F₈). The first RIE process may include using a radio frequency between 400 kilohertz (KHz) and 14 megahertz (MHz), radio frequency power less than 7 kilowatts (kW), a flow rate less than 2000 standard cubic centimeters per minute (sccm), and a pressure between 20 milla Torr (mT) and 80 mT, for a duration less than 10 minutes.

In some embodiments, the first RIE process may be configured to have a high silicon to oxide selectivity. A polymer sidewall passivation may be utilized to prevent a lateral etch of the sidewalls 340a, 340b and the insulation layer 314a.

The method 200 includes, at activity 204, forming a corner feature 330 on a plurality of corners of the substrate layer 302 adjacent to the plurality of channels 104, as illustrated in FIGS. 3C and 3D. Although four corner features 330 are illustrated in FIGS. 3C and 3D, any number of corner features 330 may be formed on any number of corners of the substrate layer 302 of any number of dies 102. The corner features 330 illustrated in FIG. 3C are shown implemented as chamfers, and are shown implemented as rounded corners (e.g., edges) in FIG. 3D.

In some embodiments, when the corner features 330 formed in activity 204 are chamfers, an angle A2 of the corner features 330 may be between 5 degrees and 45 degrees, as illustrated in FIG. 3C. The angle A2 of each of the corner features 330 may be the same, or different. In some embodiments, when the corner features 330 formed in activity 204 are rounded corners, a radius R of the corner features 330 may be between 5 μm and 20 μm, as illustrated in FIG. 3D. The radius R of the corner features 330 may be the same, or different.

In some embodiments, at least one sidewall 340a, 340b of at least one of the plurality of dies 102 may be tapered, as illustrated in FIGS. 3C and 3D. The tapered sidewalls 340a, 340b may be formed during an etch process performed during activity 204 (e.g., a second RIE process, which is described below). An angle A1 of at least one tapered sidewall 340a, 340b may be between 60 degrees and 85 degrees. The tapered sidewalls 340a, 340b may be in contrast to straight edged sidewalls that may be utilized in some portions 300 of semiconductor devices that include die-to-wafer bonding.

In some embodiments, a distance between the sidewalls 340a, 340b of the plurality of dies 102 and the global interconnects 326a, 326b, 326c, 326d included in the plurality of dies 102 and the support structure 106 may be at least 10 μm. For example, a minimum distance between any portion of the tapered sidewalls 340a, 340b may be at least 10 μm from the global interconnects 326a, 326b, 326c, 326d included in the plurality of dies 102 and the support structure 106. In some embodiments, the corner features 330 may be formed such that a distance D between the sidewalls 340a, 340b and the far edge of the corner features 330 is configured to be at least 10 μm. In some cases, the distance D may be less than the distance between the sidewalls 340a, 340b and the global interconnects 326a, 326b, 326c, 326d of the plurality of dies, as illustrated in FIGS. 3C and 3D. In other cases, the distance D (e.g., the distance D between the sidewalls 340a, 340b and the far edge of the corner features 330) may be the same as the distance between the sidewalls 340a, 340b and the global interconnects 326a, 326b, 326c, 326d of the plurality of dies. The distance D may be referred to as a guard ring, and may be configured to prevent etching of the global interconnects 326a, 326b, 326c, 326d. The entirety of the corner features 330 may be disposed between the sidewall 340a, 340b and the global interconnects 326a, 326b, 326c, 326d.

In some embodiments, a length L2 of the plurality of channels 104 from a top of the corner feature 330 on one of the plurality of dies 102 to a top of the corner feature 330 on another adjacent die 102 is between 50 μm and 4 mm, as illustrated in FIGS. 3C and 3D. In some cases, the length L2 of the channel may be measured from any part of the sidewall 340a of a die 102 to a corresponding part of the sidewall 340b of a die 102. In some cases, the length L2 of the channels 104 may be 100 μm or less. The channels 104 may each have the same length, or different lengths.

In some embodiments, forming the corner feature 330 on the plurality of corners comprises etching the corner feature 330 by a second RIE process. The second RIE process may include using at least one of SF₆, oxygen (O₂), trifluoromethane (CHF₃), C₄F₈, or CH₃F. The second RIE process may include using a radio frequency between 400 KHz and 14 MHz, RF power less than 7 kW, a flow rate less than 2000 sccm, and a pressure between 20 mT and 250 mT, for a duration less than 5 minutes. At least one of the first RIE process and the second RIE process may be implemented as a dry etch process.

In some embodiments, the second RIE process may be configured to use sidewall (e.g., sidewalls 340a, 340b) passivation and a vertical silicon etch to create the corner features 330 and the tapered sidewalls 340a, 340b illustrated in FIGS. 3C and 3D. The ratio of the silicon etchants to the various carbon passivates may be configured to tune the bonded dies 102 silicon sidewall profile angle (e.g., angle A1). The polymeric gases (e.g., CHF₃, C₄F₈) may facilitate the formation of polymerizing fluorocarbons more frequently. The O₂ may be configured to control the polymer to form the corner features 330. The Ar+ ions may provide the physical ion sputtering.

In some embodiments, forming the corner features 330 in the portion 300 of a semiconductor device may involve performing several processes. The processes may include performing an isotropic etch, performing thin polymer deposition, performing a partial vertical etch, and performing another isotropic etch and strip.

Performing the isotropic etch may be include removing a portion of the substrate layer 302 included in the plurality of dies 102 (e.g., activity 202), as illustrated in FIG. 3B. After the portion of the substrate layer 302 has been removed, thin polymer may be deposited over the portion 300 of the semiconductor device, such that the substrate layer 302 and the insulation layer 314a are covered by the deposited polymer. In some cases, the tapered sidewalls 340a, 340b may have already been formed when the thin polymer is deposited. After the thin polymer deposition, the partial vertical etch may be performed on the portion 300 of the semiconductor device, such that at least a portion of the deposited polymer over the substrate layer 302 and the tapered sidewalls 340a, 340b is removed. In some cases, after the partial vertical etch, a portion of polymer may remain disposed over at least portions of the tapered sidewalls 340a, 340b and the insulation layer 314a after the partial vertical etch is performed. The isotropic etch and strip may be performed after the partial vertical etch, such that the corner features 330 are formed on a plurality of corners of the substrate layer 302 adjacent to the plurality of channels 104 and the remaining polymer is stripped from the portion 300 of the semiconductor device, as illustrated in FIGS. 3C and 3D.

In some embodiments, the tapering of the sidewalls 340a, 340b may be formed by the second RIE process. For example, during the etching of the corner features 330, a top portion of the sidewalls 340a, 340b may be etched faster than a lower portion of the sidewalls 340a, 340b, forming the tapered sidewalls 340a, 340b illustrated in FIGS. 3C and 3D.

The method 200 may optionally include, at activity 206, planarizing the substrate layer 302 by a chemical mechanical planarization (CMP) process, as illustrated in FIG. 3D. As described above, the corner feature 330 may have a radius R between 5 μm and 20 μm after activity 206, regardless of whether the corner feature 330 was implemented as a chamfer, a rounded corner, or the like, in activity 204. For example, when the corner features 330 were implemented as chamfers (e.g., as illustrated in FIG. 3C), the corner features 330 may appear similar to or the same as the rounded corners of FIG. 3D after being planarized (e.g., activity 206). That is, the corner features 330 may be substantially rounded in shape. In these embodiments, the radius R of the corner features 330 may be between 5 μm and 20 μm, as illustrated in FIG. 3D.

The method 200 reduces the occurrence of the trapped residue (e.g., trapped residue 108) described herein, and relieves stress along sidewalls 340a, 340b of the dies 102. In addition, the method 200 reduces the formation of cracks in the insulation layers 304a, 304b, 314a, 314b included in the dies 102 and the support structure 106 during activity 206, as well as other processes utilized during formation of semiconductor devices that include die-to-wafer bonding (e.g., inter-die gap fill processes and planarization). The method 200 also mitigates defects in the portion 300 of semiconductor devices with die-to-wafer bonding.

### Additional Considerations

In the above description, details are set forth by way of example to facilitate an understanding of the disclosed subject matter. It should be apparent to a person of ordinary skill in the field, however, that the disclosed implementations are exemplary and not exhaustive of all possible implementations. Thus, it should be understood that reference to the described examples is not intended to limit the scope of the disclosure. Any alterations and further modifications to the described devices, instruments, methods, and any further application of the principles of the present disclosure are fully contemplated as would normally occur to one skilled in the art to which the disclosure relates. In particular, it is fully contemplated that the features, components, and/or steps described with respect to one implementation may be combined with the features, components, and/or steps described with respect to other implementations of the present disclosure. As used herein, the term “about” may refer to a +/−10% variation from the nominal value. It is to be understood that such a variation can be included in any value provided herein.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

As used herein, a phrase describing a range between two values includes the values of the endpoints in the range. As an example, “a value between 1 and 10” is intended to cover a range of values from 1 to 10 which includes both 1 and 10.

While the foregoing is directed to embodiments of the present disclosure, other and further embodiments of the disclosure may be devised without departing from the basic scope thereof, and the scope thereof is determined by the claims that follow.

We claim:

1. A method, comprising:
removing a portion of a substrate layer included in a plurality of dies, the plurality of dies arranged on and bonded to an insulation layer included in a support structure, wherein the plurality of dies define a plurality of channels between adjacent dies; and
forming a corner feature on a plurality of corners of the substrate layer adjacent to the plurality of channels.

2. The method of claim 1, wherein at least one sidewall of at least one of the plurality of dies is tapered, and wherein an angle of the at least one tapered sidewall is between 60 degrees and 85 degrees.

3. The method of claim 1, wherein a radius of the corner feature is between 5 micrometers (μm) and 20 μm.

4. The method of claim 1, wherein an angle of the corner feature is between 5 degrees and 45 degrees.

5. The method of claim 1, wherein a distance between a sidewall of the plurality of dies and a global interconnect included in the plurality of dies and the support structure is at least 10 micrometers (μm), and wherein the corner feature is disposed between the sidewall and the global interconnect.

6. The method of claim 1, wherein a length of the plurality of channels from a top of the corner feature on a first die of the plurality of dies to a top of the corner feature on a second die of the plurality of dies is between 50 micrometers (μm) and 4 millimeters (mm).

7. The method of claim 1, further comprising:
planarizing the substrate layer by a chemical mechanical planarization process.

8. The method of claim 1, wherein forming the corner feature on the plurality of corners comprises etching the corner feature by a first reactive ion etch (RIE) process.

9. The method of claim 8, wherein the first RIE process comprises using at least one of sulfur hexafluoride (SF₆), Oxygen (O₂), trifluoromethane (CHF₃), octafluorocyclobutane (C₄F₈), or methyl fluoride (CH₃F).

10. The method of claim 9, wherein the first RIE process comprises using a radio frequency between 400 kilohertz (KHz) and 14 megahertz (MHz), radio frequency power less than 7 kilowatts (kW), a flow rate less than 2000 standard cubic centimeters per minute (sccm), and a pressure between 20 milla Torr (mT) and 250 mT, for a duration less than 5 minutes.

11. The method of claim 10, wherein removing the portion of the substrate layer included in the plurality of dies comprises etching the portion of the substrate layer by a second RIE process.

12. The method of claim 11, wherein a ratio of a selectivity of the second RIE process between the substrate layer and the insulation layer is at least 100:1.

13. The method of claim 12, wherein the second RIE process comprises using at least one of SF₆, CH₃F, or C₄F₈.

14. The method of claim 13, wherein the second RIE process comprises using a radio frequency between 400 kilohertz (KHz) and 14 megahertz (MHz), radio frequency power less than 7 kilowatts (kW), a flow rate less than 2000 standard cubic centimeters per minute (sccm), and a pressure between 20 milla Torr (mT) and 80 mT, for a duration less than 10 minutes.

15. An interconnect structure, comprising:
a support structure including an insulation layer;
a plurality of dies arranged on and bonded to the insulation layer, wherein the plurality of dies include a substrate layer, and wherein the plurality of dies define a plurality of channels between adjacent dies; and
a corner feature included on a plurality of corners of the substrate layer adjacent to the plurality of channels.

16. The interconnect structure of claim 15, wherein at least one sidewall of at least one of the plurality of dies is tapered, and wherein an angle of the at least one tapered sidewall is between 60 degrees and 85 degrees.

17. The interconnect structure of claim 15, wherein a radius of the corner feature is between 5 micrometers (μm) and 20 μm.

18. The interconnect structure of claim 15, wherein an angle of the corner feature is between 5 degrees and 45 degrees.

19. An interconnect structure, comprising:
a support structure including an insulation layer; and
a plurality of dies arranged on and bonded to the insulation layer, wherein the plurality of dies include a substrate layer, wherein the plurality of dies define a plurality of channels between adjacent dies, and wherein at least one sidewall of at least one of the plurality of dies is tapered.

20. The interconnect structure of claim 15, further comprising:
a corner feature included on a plurality of corners of the substrate layer adjacent to the plurality of channels.
